(19) United States
(12) Patent Application Publication
(10) Pub. No.: US 2005/0263808 A1
(43) Pub. Date: Dec. 1, 2005

(54) Ferroelectric electron beam source and method for generating electron beams

(76) Inventor: Shinzo Morita, Nagoya City (JP)

Correspondence Address: GREENBERG TRAURIG LLP, 2450 COLORADO AVENUE, SUITE 400E, SANTA MONICA, CA, 90404, US

(21) Appl. No.: 11/130,528

(22) Filed: May 16, 2005

(30) Foreign Application Priority Data
May 17, 2004 (JP) 2004-146,614

(51) Int. Cl. H01L 29/76; H01L 21/00

(52) U.S. Cl. 257/295; 438/3

(57) ABSTRACT

A comb-shaped electrode is formed on the main surface of a ferroelectric thin film and a planar electrode is formed on the rear surface of a ferroelectric thin film. Then, the property of the main surface of the ferroelectric thin film is converted into semi-conduction. Then, the assembly comprised of the ferroelectric thin film, the comb-shaped electrode and the planar electrode is disposed in a given atmosphere. Under this condition, a negative voltage is applied to the comb-shaped electrode to polarize the ferroelectric thin film, and a negative impulse voltage is applied to the planar electrode, thereby generating electron beams from the main surface of the ferroelectric thin film.

### RELATED APPLICATION

This application claims the benefit of Japanese Patent Application No. 2004-146614, filed on May 17, 2004, the content of which is hereby incorporated by reference in its entirety.

### BACKGROUND

1. Field

This invention relates to a ferroelectric electron beam source and a method for generating electron beams.

2. General Background

Such a phenomenon as electron emission from a ferroelectric substance is well known, which phenomenon is originated from the change of spontaneous polarization such as phase transition of shielding electrons trapped by the ferroelectric surface. The emission electron current is weak, but high energy. For example, when a CO₂ laser was irradiated onto LiNbO₃, electron emission of 100 keV and 10⁻⁹ A/cm₂ was observed.

With the electron emission system which was established at CERN (European nuclear cooperative research organization) in 1988, electron emission with a current density of 7 A/cm₂ and an intensity of 3 KeV at maximum was realized by inverting the spontaneous polarization of a ferroelectric substance at high speed with a high speed pulsed voltage. Since then, attention is being given to such an electron beam source utilizing a ferroelectric substance for expected practical uses as a flat display or a new type process plasma source. However, if the dielectric constant of the ferroelectric substance is relatively low and the voltage-resistance of the ferroelectric substance is relatively high, the electron beam source can not generate the electron beams.

### SUMMARY

It is an object of the present invention to provide a new ferroelectric electron beam source and a new method for generating electron beams whereby electron beams with sufficient intensity can be generated even though the dielectric constant of the ferroelectric substance to be employed is low and the voltage-resistance of the ferroelectric substance to be employed is high.

In order to achieve the object, this invention relates to a ferroelectric electron beam source comprising:

a ferroelectric thin film,

a comb-shaped electrode formed on a main surface of the ferroelectric thin film, and

a planar electrode formed on a rear surface of the ferroelectric thin film which is opposite to the main surface of the ferroelectric thin film,

wherein a property of the main surface of the ferroelectric thin film is converted in semi-conduction, and a first negative voltage is applied to the comb-shaped electrode to polarize the ferroelectric thin film and a second negative voltage is applied to the planar electrode, thereby generating electron beams from the main surface of the ferroelectric thin film.

Also, this invention relates to a method for generating electron beams, comprising the steps of:

preparing a ferroelectric thin film,

forming a comb-shaped electrode on a main surface of the ferroelectric thin film,

forming a planar electrode on a rear surface of the ferroelectric thin film which is opposite to the main surface of the ferroelectric thin film,

converting a property of the main surface of the ferroelectric thin film into semi-conduction,

polarizing said ferroelectric thin film by applying a first negative voltage to the comb-shaped electrode, and

emitting electron beams from the main surface of the ferroelectric thin film by applying a second negative voltage to the planar electrode.

According to the present invention, the comb-shaped electrode and the planar electrode are provided on the main surface and the rear surface of the ferroelectric thin film, respectively, and which are opposite to one another, and the property of the main surface on which the comb-shaped electrode is provided is converted into semi-conduction. Then, the assembly comprised of the ferroelectric thin film, the comb-shaped electrode and the planar electrode is disposed in a vacuum atmosphere, and the ferroelectric thin film is polarized by applying a negative voltage to the comb-shaped electrode. In this case, a positive polarized charge is induced on the main surface of the ferroelectric thin film, and a negative polarized charge is induced on the rear surface of the ferroelectric thin film. Since the property of the main surface is converted into semi-conduction, the positive polarized charge is neutralized by the electrons from the comb-shaped electrode via the main surface.

Under this circumstance, when the polarization of the ferroelectric thin film is inverted by applying a negative voltage to the planar electrode, negative polarized charge is induced on the main surface. In this case, the electrons neutralizing the positive polarized charge induced on the main surface are sputtered through the coulomb repulsive force against the negative polarized charge, thereby generating electron beams.

In the case where the property of the main surface of the ferroelectric thin film is not converted into semi-conduction, if the ferroelectric thin film is made of a material of low dielectric constant and high voltage resistance such as polyvinylidene-fluoride (PVDF), the electrons to neutralize the positive polarized charge are not supplied on the main surface. Therefore, even though the negative voltage is applied from the planar electrode, the intended electrons cannot be generated.

In the case where the property of the main surface of the ferroelectric thin film is not converted into semi-conduction, discharge may be generated at the comb-shaped electrode through the polarization inversion, thereby deteriorating the main surface. In contrast, in the case when the property of the main surface of the ferroelectric thin film is converted into semi-conduction, the discharge can be prevented, thereby not deteriorating the main surface and realizing the electron emission. In the case where the property of the main surface of the ferroelectric thin film is converted into insulation, the electron emission cannot be realized through the polarization inversion because the electrons neutralizing the polarized charge are not generated.

In this way, according to the present invention, the intended electron beams can be generated irrespective of the magnitudes of the dielectric constant and the voltage resistance of the material making the ferroelectric thin film.

The present invention can be applied to a ferroelectric thin film with high dielectric constant and low voltage resistance in addition to the ferroelectric thin film with low dielectric constant and high voltage resistance as mentioned above. However, when the ferroelectric thin film is made of such a material with low dielectric constant and high voltage resistance as an organic ferroelectric material of PVDF, vinylidenefloride-trifluoroetylene copolymer, etc., or an inorganic ferroelectric material of lead zirconate titanate, barium titanate, etc., the intended electron beams can be generated and emit sufficiently.

In the present invention, the electron emission can be performed for a gaseous substance, a liquid substance or a solid substance disposed on the main surface of the ferroelectric thin film on which the comb-shaped electrode is provided, in addition to in vacuum. For example, when an insulative solid is disposed on the main surface of the ferroelectric thin film on which the comb-shaped electrode is disposed, the electron beams can be injected into the insulative solid. Therefore, if a given dye is incorporated in the insulative solid, the dye is excited by the electron beams, thereby generating a light with a given wavelength from the insulative solid.

The conversion of the main surface of the ferroelectric thin film into semi-conduction can be realized by forming a given semi-conductive thin film on the main surface or performing conducting treatment such as etching treatment using etchant or plasma treatment.

Herein, the term “semi-conduction” means an intermediate electric property between metallic conductor and insulator that does not flow current.

According to the present invention, a new ferroelectric electron beam source and a new method for generating electron beams is provided whereby electron beams with sufficient intensity can be generated even though the dielectric constant of the ferroelectric substance to be employed is low and the voltage-resistance of the ferroelectric substance to be employed is high.

### BRIEF DESCRIPTION OF THE DRAWINGS

FIG. 1 is a cross-sectional view illustrating a ferroelectric electron beam source according to the present invention, and

FIG. 2 is a top plan view of the ferroelectric electron beam source illustrated in FIG. 1.

### DETAILED DESCRIPTION OF THE DRAWINGS

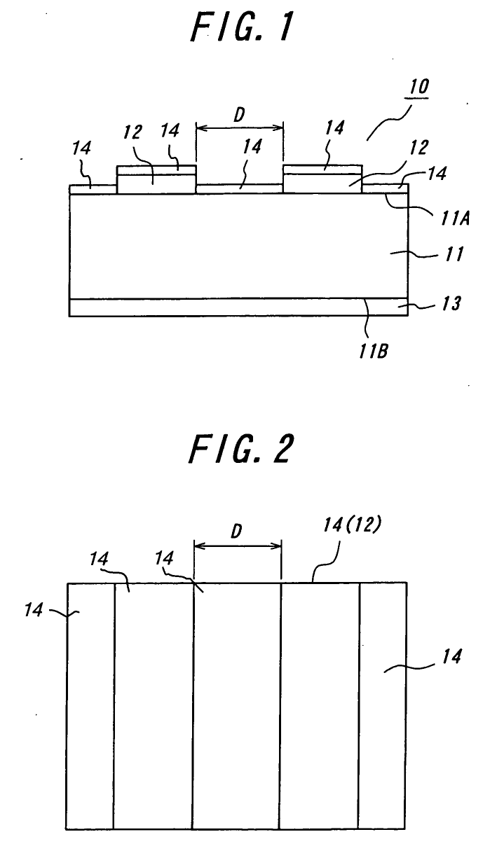

FIG. 1 is a cross-sectional view illustrating a ferroelectric electron beam source according to the present invention, and FIG. 2 is a top plan view of the ferroelectric electron beam source illustrated in FIG. 1. The ferroelectric electron beam source 10 illustrated in FIGS. 1 and 2 includes a ferroelectric thin film 11, a comb-shaped electrode 12 formed on the main surface 11A of the ferroelectric thin film 11 and a planar electrode 13 formed on the rear surface 11B of the thin film 11. As is apparent from FIG. 2, the comb-shaped electrode 12 is an elongated strip on the main surface 11A of the ferroelectric thin film 11. The planar electrode 13 is formed so as to cover the rear surface 11B of the ferroelectric thin film 11.

As is not apparent from the drawings, the rims of the comb-shaped electrode 12 and the planar electrode 13 are removed through etching so as to prevent a discharge between the electrodes.

In the ferroelectric electron beam source 10 illustrated in FIGS. 1 and 2, the ferroelectric thin film 11 may be made of any material exhibiting ferroelectric properties, but preferably made of a material with low dielectric constant and high voltage resistance such as an organic ferroelectric material of PVDF, vinylidenefloride-trifluoroetylene copolymer, etc., or an inorganic ferroelectric material of lead zirconate titanate, barium titanate, etc. In this case, the thickness of the ferroelectric thin film 11 is preferably set within 1-2000 μm. If the thickness of the ferroelectric thin film 11 is set beyond 1000 μm, the absolute value of the impulse voltage to be applied to the ferroelectric thin film 11 becomes large in the order of several thousands volts, for example, in the electron beam generating method which will be described below, thereby deteriorating the operationality of the ferroelectric electron beam source 10. On the other hand, if the thickness of the ferroelectric thin film 11 is set below 1 μm, the ferroelectric electron beam source may be difficult to use as a light-emitting device.

The comb-shaped electrode 12 and the planar electrode 13 may be made of a normal material such as Au, Ag, Cu, Al. The distance (pitch) D between the rods of the comb-shaped electrode 12 is preferably set to the thickness of the ferroelectric thin film 11 if the ferroelectric thin film 11 is made of the above-mentioned preferable material with low dielectric constant and high voltage resistance and the thickness of the ferroelectric thin film 11 is set to the above-mentioned preferable range.

The semi-conductive film 14 may be made of any kind of material provided that the intended electron beams can be emitted through the polarization-inverting operation, but preferably made of C—Au—S, C—Cu—S, C—Fe—S or the like. The thickness of the semi-conductive film 14 is set within 0.5-10 nm.

Now, the method of generating electron beams utilizing the ferroelectric electron beam source 10 illustrated in FIGS. 1 and 2 will be described. First of all, the assembly comprised of the ferroelectric thin film 11, the comb-shaped electrode 12 and the planar electrode 13 is disposed in a given atmosphere. Then, a given negative voltage is applied to the comb-shaped electrode 12 to polarize the ferroelectric thin film 11. In this case, positive polarized charge is induced on the main surface 11A of the ferroelectric thin film 11. On the other hand, the positive polarized charge is neutralized by the electrons from the comb-shaped electrode 12 via the semi-conductive film 14.

Under this circumstance, a negative impulse voltage is applied to the planar electrode 13 to invert the polarization of the ferroelectric thin film 11. In this case, since negative polarized charge is induced on the main surface 11, the electrons neutralizing the positive polarized charge induced on the main surface 11A are sputtered through the coulomb repulsive force against the negative polarized charge, thereby generating the intended electron beams.

The intended electron beams can be generated by applying an AC voltage with appropriately controlled frequency to the comb-shaped electrode 12 and the planar electrode 13, instead of the application of the negative impulse voltage.

In the case where the semi-conductive film 14 is not formed on the main surface 11A of the ferroelectric thin film 11, if the ferroelectric thin film 11 is made of a material with low dielectric constant and high voltage resistance such as PVDF, the electrons to neutralize the positive polarized charge are not supplied onto the main surface 11A even though the positive polarized charge is induced on the main surface 11A as mentioned above. Therefore, when the negative impulse voltage is applied from the planar electrode 13, the intended electron beams can not be generated.

If a given insulative solid is disposed on the main surface 11A of the ferroelectric thin film 11 via the semi-conductive thin film 14, the electron beams can be injected into the insulative solid. In this point of view, if a given dye is incorporated into the insulative solid, a light originated from the dye can be generated through the excitation of the dye. If a thin film with a given energy band structure is formed on the main surface 11A, a light originated from the recombination of electrons and holes can be generated.

If another solid substance, gaseous substance or liquid substance is disposed on the main surface 11A, instead of the above-mentioned insulative solid, the electron beams can be injected into the substance.

### EXAMPLE

A PVDF sheet with a thickness of 40 μm was prepared, and an Al comb-shaped electrode with a rod distance (pitch) of 50 μm was formed on the main surface of the sheet, and an Al planar electrode was formed on the rear surface of the sheet. Then, the assembly comprised of the sheet and the electrodes was disposed in a vacuum atmosphere under a pressure of 10⁻⁴ Torr or below. When a negative voltage of −450V was applied to the comb-shaped electrode and a negative impulse voltage of −2400V was applied to the planar electrode, electron beams with a charge of 6.1×10⁻¹²C can be generated.

Although the present invention was described in detail with reference to the above examples, this invention is not limited to the above disclosure and every kind of variation and modification may be made without departing from the scope of the present invention.

For example, in the above embodiment, although the semi-conductive film 14 is formed on the main surface 11A of the ferroelectric thin film 11 such that the property of the main surface 11A is converted into semi-conduction, the property of the main surface 11A can be also converted into semi-conduction through conducting treatment such as plasma treatment or etching treatment using etchant for the main surface 11A. The etching treatment can be carried out by using Na treatment (treatment using an etchant with metallic Na immersed in an oil). The plasma treatment can be carried out by using Ar₂, N₂ or O₂ plasma.

While the apparatus and method have been described in terms of what are presently considered to be the most practical and preferred embodiments, it is to be understood that the disclosure need not be limited to the disclosed embodiments. It is intended to cover various modifications and similar arrangements included within the spirit and scope of the claims, the scope of which should be accorded the broadest interpretation so as to encompass all such modifications and similar structures. The present disclosure includes any and all embodiments of the following claims.

1. A ferroelectric electron beam source comprising:
a ferroelectric thin film,
a comb-shaped electrode formed on a main surface of said ferroelectric thin film, and
a planar electrode formed on a rear surface of said ferroelectric thin film which is opposite to said main surface of said ferroelectric thin film,
wherein a property of said main surface of said ferroelectric thin film is converted into semi-conduction, and a first negative voltage is applied to said comb-shaped electrode to polarize said ferroelectric thin film and a second negative voltage is applied to said planar electrode, thereby generating electron beams from said main surface of said ferroelectric thin film.

2. The ferroelectric electron beam source as defined in claim 1, wherein said ferroelectric thin film is made of at least one of polyvinylidene-fluoride (PVDF) and vinylidenefloride-trifluoroetylene copolymer.

3. The ferroelectric electron beam source as defined in claim 1, wherein said ferroelectric thin film is made of at least one of lead zirconate titanate and barium titanate.

4. The ferroelectric electron beam source as defined in claim 2, wherein a thickness of said ferroelectric thin film is set within 1-100 μm.

5. The ferroelectric electron beam source as defined in claim 3, wherein a thickness of said ferroelectric thin film is set within 1-100 μm.

6. The ferroelectric electron beam source as defined in claim 1, wherein a distance (pitch) between rods of said comb-shaped electrode is set equal to the thickness of the ferroelectric thin film.

7. The ferroelectric electron beam source as defined in claim 1, wherein said property of said main surface of said ferroelectric thin film is converted in semi-conduction by forming a semi-conductive thin film on said main surface of said ferroelectric thin film.

8. The ferroelectric electron beam source as defined in claim 7, wherein said semi-conductive thin film is made of at least one selected from the group consisting of C—Au—S, C—Cu—S and C—Fe—S.

9. The ferroelectric electron beam source as defined in claim 8, wherein a thickness of said semi-conductive thin film is set within 0.5-10 nm.

10. The ferroelectric electron beam source as defined in claim 1, wherein said property of said main surface of said ferroelectric thin film is converted in semi-conduction by performing conducting treatment for said main surface of said ferroelectric thin film.

11. The ferroelectric electron beam source as defined in claim 1, wherein a gaseous substance, a liquid substance or a solid substance is disposed on said main surface of said ferroelectric thin film such that said electron beams are injected into said gaseous substance, said liquid substance or said solid substance.

12. A method for generating electron beams, comprising the steps of:
preparing a ferroelectric thin film,
forming a comb-shaped electrode on a main surface of said ferroelectric thin film,
forming a planar electrode on a rear surface of said ferroelectric thin film which is opposite to said main surface of said ferroelectric thin film,
converting a property of said main surface of said ferroelectric thin film into semi-conduction,
polarizing said ferroelectric thin film by applying a first negative voltage to said comb-shaped electrode, and
emitting electron beams from said main surface of said ferroelectric thin film by applying a second negative voltage to said planar electrode.

13. The generating method as defined in claim 12, wherein said ferroelectric thin film is made of at least one of polyvinylidene-fluoride (PVDF) and vinylidenefloride-trifluoroetylene copolymer.

14. The generating method as defined in claim 12, wherein said ferroelectric thin film is made of at least one of lead zirconate titanate and barium titanate.

15. The generating method as defined in claim 13, wherein a thickness of said ferroelectric thin film is set within 1-1000 μm.

16. The generating method as defined in claim 14, wherein a thickness of said ferroelectric thin film is set within 1-1000 μm.

17. The generating method as defined in claim 12, wherein a distance (pitch) between rods of said comb-shaped electrode is set equal to the thickness of the ferroelectric thin film.

18. The generating method as defined in claim 12, wherein said property of said main surface of said ferroelectric thin film is converted in semi-conduction by forming a semi-conductive thin film on said main surface of said ferroelectric thin film.

19. The generating method as defined in claim 18, wherein said semi-conductive thin film is made of at least one selected from the group consisting of C—Au—S, C—Cu—S and C—Fe—S.

20. The generating method as defined in claim 19, wherein a thickness of said semi-conductive thin film is set within 0.5-10 nm.

21. The generating method as defined in claim 12, wherein said property of said main surface of said ferroelectric thin film is converted in semi-conduction by performing conducting treatment for said main surface of said ferroelectric thin film.

22. The generating method as defined in claim 12, further comprising the step of disposing a gaseous substance, a liquid substance or a solid substance on said main surface of said ferroelectric thin film such that said electron beams are injected into said gaseous substance, said liquid substance or said solid substance.
